(19) United States
(12) Patent Application Publication
(10) Pub. No.: US 2022/0268821 A1
(43) Pub. Date: Aug. 25, 2022

(54) FUEL CELL VEHICLE INSULATION RESISTOR FAULT DETECTION SYSTEM AND METHOD

(71) Applicants: Ceres Intellectual Property Company Limited, Horsham (GB); Weichai Power Co., Ltd., Weifang, Shandong (CN)

(72) Inventor: Lei Sun, Weifang, Shandong (CN)

(21) Appl. No.: 17/629,232

(22) PCT Filed: Sep. 23, 2020
(86) PCT No.: PCT/IB2020/058889

§ 371 Date: Jan. 21, 2022

(30) Foreign Application Priority Data
Jul. 23, 2019 (CN) 201921168691.0

(51) Int. Cl. G01R 27/02; G01R 31/52; B60L 3/00; B60L 58/30

(52) U.S. Cl. CPC G01R 27/025; G01R 31/52; B60L 3/0069; B60L 3/0053; B60L 3/0046; B60L 58/30

(57) ABSTRACT

A fuel cell vehicle insulation resistor fault detection system, comprising: a stack, a stack pre-charge circuit, a power cell, a power distribution controller, a high voltage component, a VCU (vehicle control unit) and at least one insulation detector. The stack is connected to the stack pre-charge circuit, the stack pre-charge circuit is connected to the power cell, the power cell is connected to the power distribution controller, the power distribution controller is connected to the high voltage component and the VCU is connected to the insulation detector. When the insulation detector is used to detect whether the insulation resistor of the stack is faulty, the stack is connected to the insulation detector; when the insulation detector is used to detect whether the insulation resistor of the power cell is faulty, the power cell is connected to the insulation detector; and when the insulation detector is used to detect whether the insulation resistor of the high voltage component is faulty, the power distribution controller is connected to the insulation detector. When an insulation resistor of the fuel cell vehicle is faulty, the source of the insulation resistor fault can be located in time.

### TECHNICAL FIELD

The present application relates to the technical field of fault detection, particularly to a fuel cell vehicle insulation resistor fault detection system and method.

### BACKGROUND ART

A fuel cell vehicle, also known as a new type of environmentally friendly vehicle, is a vehicle that uses electricity generated by a vehicle-mounted fuel cell device for power. In the vehicle-mounted fuel cell device, hydrogen as a fuel undergoes a redox reaction with oxygen in the atmosphere to generate electricity, which drives a motor to perform work. The motor drives the mechanical transmission structure in the car, which drives the front axle (or rear axle) and other moving mechanical structures of the car to operate, thereby driving the electric vehicle.

When the insulation resistor of an existing fuel cell vehicle is faulty, the source of the insulation resistor fault may be difficult to locate, so it is impossible to carry out effective repair against the source of the insulation resistor fault, resulting in poor safety performance and high risk to the fuel cell vehicle.

### SUMMARY

One aspect of the invention provides a fuel cell vehicle insulation resistor fault detection system so that when an insulation resistor of the fuel cell vehicle is faulty, the source of the insulation resistor fault can be located in time based on the system, thereby carrying out effective repair against the source of the insulation resistor fault to improve the safety performance of the fuel cell vehicle and lower the risk.

The system comprises: a stack, a stack pre-charge circuit, a power cell, a power distribution controller, a high voltage component, a vehicle control unit (VCU) and at least one insulation detector.

The stack is connected to the stack pre-charge circuit, the stack pre-charge circuit is connected to the power cell, the power cell is connected to the power distribution controller, the power distribution controller is connected to the high voltage component and the VCU is connected to the insulation detector;

When the insulation detector is used to detect whether the insulation resistor of the stack is faulty, the stack is connected to the insulation detector; when the insulation detector is used to detect whether the insulation resistor of the power cell is faulty, the power cell is connected to the insulation detector; and when the insulation detector is used to detect whether the insulation resistor of the high voltage component is faulty, the power distribution controller is connected to the insulation detector.

The system can further comprise a voltage converter connected to the stack pre-charge circuit and the power cell respectively.

The insulation detector can comprise a first insulation detector, a second insulation detector and a third insulation detector.

The first insulation detector can be connected to the stack to detect whether the insulation resistor of the stack is faulty; the second insulation detector can be connected to the power cell to detect whether the insulation resistor of the power cell is faulty; and the third insulation detector can be connected to the high voltage component to detect whether the insulation resistor of the high voltage component is faulty.

The stack can comprise a fuel cell controller.

A second aspect of the invention provides a fuel cell vehicle insulation resistor fault detection method for a system comprising a stack, a stack pre-charge circuit, a power cell, a power distribution controller, a high voltage component, a vehicle control unit (VCU), and at least one insulation detector; wherein the stack is connected to the stack pre-charge circuit, the stack pre-charge circuit is connected to the power cell, the power cell is connected to the power distribution controller, the power distribution controller is connected to the high voltage component, and the VCU is connected to the insulation detector; the method comprising at least one of: connecting the stack to the insulation detector to detect whether the insulation resistor of the stack is faulty; connecting the power cell to the insulation detector to detect whether the insulation resistor of the power cell is faulty; and connecting the power distribution controller to the insulation detector to detect whether the insulation resistor of the high voltage component is faulty.

The insulation detector can comprise a first insulation detector, a second insulation detector, and a third insulation detector; and the method can further comprises at least one of connecting the first insulation detector to the stack to detect whether the insulation resistor of the stack is faulty; connecting the second insulation detector to the power cell to detect whether the insulation resistor of the power cell is faulty; and connecting the third insulation detector to the high voltage component to detect whether the insulation resistor of the high voltage component is faulty.

In the foregoing embodiments, an insulation detector is connected to the insulation resistor that might be faulty. When an insulation resistor is faulty, the insulation detector can be used to detect whether the faulty insulation resistor is the insulation resistor currently detected by the insulation detector, thereby quickly locating the source of the insulation resistor fault. Specifically, the fuel cell vehicle insulation resistor fault detection system can comprise a stack, a stack pre-charge circuit, a power cell, a power distribution controller, a high voltage component, a VCU and at least one insulation detector; the stack is connected to the stack pre-charge circuit, the stack pre-charge circuit is connected to the power cell, the power cell is connected to the power distribution controller, the power distribution controller is connected to the high voltage component and the VCU is connected to the insulation detector. When an insulator resistor in the stack is faulty and needs to be detected, an insulation detector can be connected and used to detect whether the insulator resistor in the stack is faulty. Similarly, when the insulation detector is to be used to detect whether the insulation resistance of the power cell is faulty, the power cell is connected to the insulation detector; and when the insulation detector is to be used to detect whether the insulation resistor of the high voltage component is faulty, the power distribution controller is connected to the insulation detector. It can be seen that an insulation detector is arranged at the location where an insulation resistor fault might occur in the fuel cell vehicle insulation resistor fault detection system, so when an insulation resistor fault occurs in the fuel cell vehicle, the fault of the insulation resistor can be detected using the insulation detector arranged at the location, thereby achieving fast locating of the insulation resistor fault source and allowing timely repair against the insulation resistor fault source to improve the safety performance of the fuel cell vehicle and lower the risk.

### BRIEF DESCRIPTION OF THE DRAWINGS

In order to more clearly describe the technical solutions in the embodiments of the present application, the drawings are briefly described below. Obviously, the drawings in the description below are just some embodiments of the present application.

FIG. 1 is a structural schematic view of a fuel cell vehicle insulation resistor fault detection system.

FIG. 2 is a structural schematic view of an alternative fuel cell vehicle insulation resistor fault detection system.

### DETAILED DESCRIPTION

The use of fuel cell vehicles as means of transport can significantly reduce pollution. It is a means of transport that is increasingly accepted by people. However, the existing fuel cell vehicles do not have a fault locating function for insulation resistors. In other words, when an insulation resistor fault happens in a fuel cell vehicle, it is impossible to accurately locate which insulation resistor is faulty, thereby being unable to carry out effective repair against the insulation resistor fault source. Failure to repair an insulation resistor fault in time will lower the safety performance of the existing fuel cell vehicle and raise the risk.

An embodiment of the present application provides a fuel cell vehicle insulation resistor fault detection system. An insulation detector is located at the insulation resistor that might be faulty. When an insulation resistor is faulty, the insulation detector can be used to detect whether the faulty insulation resistor is the insulation resistor currently detected by the insulation detector, thereby quickly locating the source of the insulation resistor fault. Specifically, the fuel cell vehicle insulation resistor fault detection system can comprise a stack, a stack pre-charge circuit, a power cell, a power distribution controller, a high voltage component, a VCU and at least one insulation detector. The stack is connected to the stack pre-charge circuit, the stack pre-charge circuit is connected to the power cell, the power cell is connected to the power distribution controller, the power distribution controller is connected to the high voltage component and the VCU is connected to the insulation detector. When the insulator resistor in the stack is faulty and needs to be detected, an insulation detector can be connected there and used to detect whether the insulator resistor in the stack is faulty. Now, the stack is connected to the insulation detector; similarly, when the insulation detector is used to detect whether the insulation resistance of the power cell is faulty, the power cell is connected to the insulation detector; and when the insulation detector is used to detect whether the insulation resistor of the high voltage component is faulty, the power distribution controller is connected to the insulation detector. It can be seen that an insulation detector is arranged at the location where an insulation resistor fault might occur in the fuel cell vehicle insulation resistor fault detection system, so when an insulation resistor fault happens to the fuel cell vehicle, the fault of the insulation resistor can be detected using the insulation detector arranged at the location, thereby achieving fast locating of the insulation resistor fault source and carrying out timely repair against the insulation resistor fault source to improve the safety performance of the fuel cell vehicle and lower the risk.

In order to illustrate the foregoing objects, features and advantages of the present invention, various non-limiting embodiments will be described in an exemplary manner below in conjunction with the accompanying drawings. Obviously, the described embodiments are not all of the embodiments of the invention. Based on the described embodiments, other embodiments can be obtained by those of ordinary skill in the art without creative work within the scope of the claims.

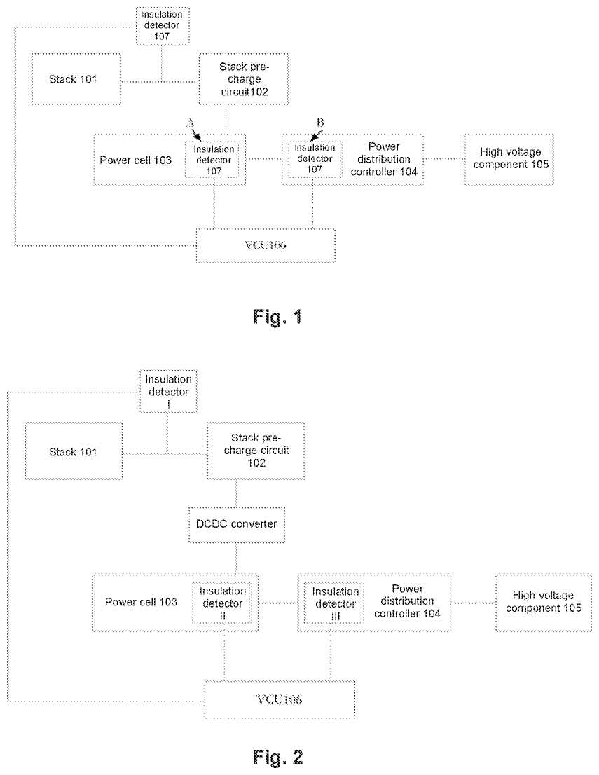

FIG. 1 is a structural schematic view of a fuel cell vehicle insulation resistor fault detection system in an embodiment of the present application. The system 100 specifically comprises:

a stack 101, a stack pre-charge circuit 102, a power cell 103, a power distribution controller 104, a high voltage component 105, a VCU 106 and at least one insulation detector 107.

The stack 101 is connected to the stack pre-charge circuit 102, the stack pre-charge circuit 102 is connected to the power cell 103, the power cell 103 is connected to the power distribution controller 104, the power distribution controller 104 is connected to the high voltage component 105 and the VCU 106 is connected to the insulation detector 107.

It should be noted that as shown in FIG. 1, the insulation detector 107 can be connected to the stack 101. When an insulation resistor fault happens to the fuel cell vehicle, the fuel cell vehicle can use this insulation detector 107 to detect and determine whether the insulator resistor in the stack 101 is faulty so that when the insulator resistor in the stack 101 is faulty, it can be quickly located based on this insulation detector 107, while when the insulator resistor in the stack 101 is not faulty, it can be determined based on this insulation detector 107 that the source of the insulation resistor fault is not inside the stack 101. In specific implementation, before the main relay of the stack pre-charge circuit 102 is closed, the insulation detector 107 may keep detecting whether the insulation resistor of the stack 101 is faulty, while when the main relay of the stack pre-charge circuit 102 is closed, the insulation detector 107 may stop the insulation detection of the insulation resistor.

When the insulation detector 107 is connected to the stack 101, the insulation detector 107 specifically may be located in front of the electrical loop of the stack pre-charge circuit.

The location of the insulation detector 107 in the fuel cell vehicle insulation resistor fault detection system shown in FIG. 1 is only one example. In other possible implementation manners, the insulation detector 107 can be connected to the power cell 103, i.e., the insulation detector 107 is installed at the dash line location A as shown in FIG. 1 so as to use the insulation detector 107 installed at the dash line location A to detect whether a fault happens to the insulation resistor in the power cell 103. Of course, the insulation detector 107 can be connected to the high voltage component 105, too, i.e., the insulation detector 107 is installed at the dash line location B as shown in FIG. 1 so as to use the insulation detector 107 installed at the dash line location B to detect whether a fault happens to the insulation resistor in the high voltage component 105.

In this way, as an insulation detector 107 is arranged at the location where an insulation resistor fault might occur in the fuel cell vehicle insulation resistor fault detection system. When an insulation resistor fault happens to the fuel cell vehicle, the fault of the insulation resistor can be detected using the insulation detector 107 arranged at the location (i.e., the insulation resistor in the stack 101, the insulation resistor in the power cell 103 or the insulation resistor in the high voltage component 105), thereby achieving fast locating of the insulation resistor fault source and allowing timely repair against the insulation resistor fault source to improve the safety performance of the fuel cell vehicle and lower the risk.

In practical application, in the stack 101 the fuel (which specifically can be high purity hydrogen, or hydrogen containing fuel, etc.) may undergo an electrochemical reaction with oxygen in the atmosphere or oxygen carried by the car to generate an electrical current, which is output to the stack pre-charge circuit 102. As an example, the specific principle for generation of current is as follows: hydrogen or hydrogen-containing gaseous fuel is input to the anode (fuel electrode) of the cell. Hydrogen molecules are dissociated into hydrogen ions (H+) and electrons (e−) under the action of the anode catalyst. H+ penetrates the electrolyte layer of the fuel cell and moves toward the cathode (oxidation electrode), while e− cannot pass through the electrolyte layer and so flow toward the cathode from an external circuit. Oxygen is input to the cathode of the cell (it can be the oxygen in the atmosphere, or oxygen configured in the car). The oxygen is dissociated into oxygen atoms under the action of the cathode catalyst. The oxygen atoms are combined with e− that flow toward the cathode from an external circuit and H+ of the fuel that penetrates the electrolyte to generate water (H₂O) with a stable structure, hence completing the electrochemical reaction and releasing heat. As long as hydrogen is continuously input to the anode and oxygen is continuously input to the cathode, the electrochemical reaction will go on continuously and e− will flow continuously through an external circuit to form a current.

Further, the stack 101 may also comprise a fuel cell controller, which can control the flow of fuel gas (such as hydrogen or other hydrogen-containing gaseous fuel) or air/oxygen and can collect the temperature signal and pressure signal of the stack 101 to facilitate the acquisition of temperature, pressure and other parameters in the stack 101. When the temperature or pressure in the stack 101 is too high, the temperature or pressure of the stack 101 can be reduced by adjusting the flow of fuel gas or air.

After the stack pre-charge circuit 102 receives DC current output by the stack 101, it can precharge the DC current to protect the capacitors in the circuit through which the current passes.

After the stack pre-charge circuit 102 finishes pre-charging of the DC current, it can input the pre-charged current into the power cell 103 through the circuit connection with the power cell 103 to provide the fuel cell vehicle with a power source with a high power response rate to meet the requirements of the electric vehicle for instantaneous power. In practical application, the power cell 103 may comprise a battery management system (BMS) to control a power transmission process during charging or discharging of the power cell.

In some implementations, as electric leakage caused by an insulation resistor fault during charging or discharging of the power cell 103 may damage the power cell 103 or other circuits, an insulation detector 107 can be installed in the power cell 103 and is used to perform insulation detection of the insulation resistor in the power cell 103. In one implementation, before the main relay in the power cell 103 is closed, the insulation detector 107 can be in an operating state all the time, i.e., it detects whether the insulation resistor in the power cell 103 is faulty when the power cell 103 is in a charging state or the power cell outputs power. When the main relay of the power cell 103 is closed, the insulation detector 107 can stop the insulation detection of the insulation resistor.

Further, the current output or input when the power cell 103 is performing charging or discharging shall have certain voltage, so voltage conversion can be set between the stack pre-charge circuit 102 and the power cell 103. After the pre-charged direct current output by the stack pre-charge circuit 102 passes the voltage converter, the voltage converter can convert this direct current into a voltage needed for input into the power cell 103 and connect the voltage to the DC bus of the power cell 103. As an example, as the voltage output by the stack pre-charge circuit 102 might be smaller than the voltage of the power cell (such as 450V or 700V), the voltage converter specifically can be a booster-type DC-DC (Direct current-Direct current) converter or an upgraded booster-type DC-DC converter.

As the power provided by the power cell 103 may support the operation of a plurality of high voltage components 105, in this embodiment, a power distribution controller can be used to distribute DC bus power supply on the power cell 103 for different high voltage components 105 and transmit it to different high voltage components 105. As an example, the high voltage components 105 specifically can be a motor controller, a steering pump DCAC (Direct current-Alternating current), an air compressor DCAC, an electromotive air conditioner and PTC (Positive Temperature Coefficient, which can also be called auto heater on a car).

Similarly, if an insulation resistor of the high voltage component 105 is faulty, specifically the faulty insulation resistor can be the insulation resistor on the DC bus between the high voltage component 105 and the power distribution controller 104, it may cause electric leakage of the insulation resistor in the course of work, resulting in damage of the power distribution controller 104 or the high voltage component 105. Therefore, the insulation detector 107 can be installed in the power distribution controller 104 to perform insulation detection of the insulation resistor on the DC bus between the power distribution controller 104 and the high voltage component 105. In specific implementation, when the car key in the car is in an ON position, the insulation detector 107 in the power distribution controller 104 can detect the high voltage on the high voltage component 105 and whether the insulation resistor of the DC bus is faulty when the voltage is not high. When the car key in the car is in an OFF position, the insulation detector 107 can stop insulation detection of the insulation resistor.

The insulation detection result of the insulation detector 107 at a corresponding position can be sent to the vehicle control unit (VCU) 106 in form of a message. Specifically, the insulation detector 107 can be connected to the VCU 106 through a CAN bus and after obtaining an insulation detection result regarding an insulation resistor, the insulation detector 107 can create a message based on the insulation detection result and send this message to the VCU 106 through the CAN bus so that the VCU 106 can judge based on the received message whether the insulation resistor detected by the insulation detector 107 is faulty.

It should be noted that the number of the insulation detectors 107 shown in FIG. 1 is one. In practical application, a plurality of insulation detectors can be installed in the fuel cell vehicle insulation resistor fault detection system to perform fault detection and troubleshooting of the insulation resistors in a plurality of positions, i.e., a plurality of insulation detectors can be added on the basis of the fuel cell vehicle insulation resistor fault detection system shown in FIG. 1.

As shown in FIG. 2, an insulation detector I, an insulation detector II and an insulation detector III can be arranged in the stack 101, the power cell 103 and the power distribution controller 104 respectively so that three different insulation detectors are used to detect the insulation of the insulation resistors in three different positions and when a fault happens to the fuel cell vehicle, which of the insulation resistors in the three positions is faulty can be detected based on these three insulation detectors, thus achieving quick locating of the insulation resistor fault source and allowing timely maintenance against the insulation resistor fault source to improve the safety performance of the fuel cell vehicle and lower the risk.

Further, in the fuel cell vehicle insulation resistor fault detection system shown in FIG. 2, a DCDC converter is added (i.e., the voltage converter mentioned in the foregoing embodiment). The DCDC converter can be connected to the stack pre-charge circuit 102 and the power cell 103 respectively and is used to boost the direct current output by the stack pre-charge circuit 102 from a low voltage to a voltage required for input into the power cell 103, or reduce the direct current output by the stack pre-charge circuit 102 from a high voltage to a voltage required for input into the power cell 103.

“First insulation detector” and other names mentioned in the embodiments of the present application are used as name identifications and do not represent “first” in order. This rule also applies to “second”, “third”, etc.

The embodiments in the description are all described in a progressive manner and the same or similar parts among the embodiments can be mutually referred to, and each embodiment focuses on the differences from other embodiments. The device embodiment described above is only schematic, wherein the elements described as separate components may be or may not be physically separated, or may be or may not be physical modules, i.e., they may be located in one place, or may be distributed to a plurality of network units. Some or all of the modules can be selected according to the actual needs to achieve the object of the solution of this embodiment.

The above are only exemplary implementations of the present invention.

1. A fuel cell vehicle insulation resistor fault detection system, wherein the system comprises:
a stack,
a stack pre-charge circuit,
a power cell,
a power distribution controller,
a high voltage component,
a vehicle control unit (VCU), and
at least one insulation detector;
wherein
the stack is connected to the stack pre-charge circuit,
the stack pre-charge circuit is connected to the power cell,
the power cell is connected to the power distribution controller,
the power distribution controller is connected to the high voltage component, and
the VCU is connected to the insulation detector; and
when the insulation detector is used to detect whether the insulation resistor of the stack is faulty, the stack is connected to the insulation detector;
when the insulation detector is used to detect whether the insulation resistor of the power cell is faulty, the power cell is connected to the insulation detector; and
when the insulation detector is used to detect whether the insulation resistor of the high voltage component is faulty, the power distribution controller is connected to the insulation detector.

2. The system according to claim 1, wherein
the system further comprises a voltage converter; and
the voltage converter is connected to the stack pre-charge circuit and the power cell respectively.

3. The system according to claim 1, wherein the insulation detector comprises:
a first insulation detector,
a second insulation detector, and
a third insulation detector;
wherein:
the first insulation detector is connected to the stack to detect whether the insulation resistor of the stack is faulty;
the second insulation detector is connected to the power cell to detect whether the insulation resistor of the power cell is faulty; and
the third insulation detector is connected to the high voltage component to detect whether the insulation resistor of the high voltage component is faulty.

4. The system according to claim 1, wherein the stack comprises a fuel cell controller.

5. A fuel cell vehicle insulation resistor fault detection method for a system comprising:
a stack,
a stack pre-charge circuit,
a power cell,
a power distribution controller,
a high voltage component,
a vehicle control unit (VCU), and
at least one insulation detector;
wherein
the stack is connected to the stack pre-charge circuit,
the stack pre-charge circuit is connected to the power cell,
the power cell is connected to the power distribution controller,
the power distribution controller is connected to the high voltage component, and
the VCU is connected to the insulation detector;
the method comprising at least one of:
connecting the stack to the insulation detector to detect whether the insulation resistor of the stack is faulty;
connecting the power cell to the insulation detector to detect whether the insulation resistor of the power cell is faulty; and
connecting the power distribution controller to the insulation detector to detect whether the insulation resistor of the high voltage component is faulty.

6. The method according to claim 5, wherein the system further comprises a voltage converter, connected to the stack pre-charge circuit and the power cell respectively.

7. The method according to claim 5, wherein the insulation detector comprises:
a first insulation detector,
a second insulation detector, and
a third insulation detector;
wherein the method further comprises at least one of:
connecting the first insulation detector to the stack to detect whether the insulation resistor of the stack is faulty;
connecting the second insulation detector to the power cell to detect whether the insulation resistor of the power cell is faulty; and
connecting the third insulation detector to the high voltage component to detect whether the insulation resistor of the high voltage component is faulty.

8. The method according to claim 5, wherein the stack comprises a fuel cell controller.
